(19) United States
(12) Patent Application Publication
(10) Pub. No.: US 2013/0107481 A1
(43) Pub. Date: May 2, 2013

(54) MULTI-PIECE SUBSTRATE

(71) Applicants: Keisuke SHIMIZU, Ogaki-shi (JP); Yasuyuki Kurabe, Ogaki-shi (JP)

(72) Inventors: Keisuke SHIMIZU, Ogaki-shi (JP); Yasuyuki Kurabe, Ogaki-shi (JP)

(21) Appl. No.: 13/664,577

(22) Filed: Oct. 31, 2012

(30) Foreign Application Priority Data
Nov. 2, 2011 (JP) 2011-241047

(51) Int. Cl. H05K 7/14

(52) U.S. Cl. 361/761

(57) ABSTRACT

A multi-piece substrate includes a frame portion, and a unit portion in which multiple wiring boards is arrayed. The frame portion is formed on the periphery of the unit portion, the wiring boards have semiconductor elements built in the wiring boards, respectively, and the frame portion has multiple slits formed such that the slits have openings on the periphery of the frame portion.

### CROSS-REFERENCE TO RELATED APPLICATIONS

The present application is based upon and claims the benefit of priority from Japanese Application No. 2011-241047, filed Nov. 2, 2011, the entire contents of which are incorporated herein by reference.

### BACKGROUND OF THE INVENTION

1. Field of the Invention

The present invention relates to a multi-piece substrate where multiple printed wiring boards with built-in ceramic semiconductor elements are arrayed in a matrix. Such a multi-piece substrate is divided into individual printed wiring boards after electronic components are mounted on the printed wiring boards.

2. Description of Background Art

Small printed wiring boards are manufactured by arraying multiple printed wiring boards in a matrix as a large multi-piece substrate and by dividing the printed wiring boards of the multi-piece substrate into individual units. Japanese Patent Publication No. 3380097 describes a substrate for semiconductor devices to be divided into individual units. Japanese Laid-Open Patent Publication No. 2002-246757 describes a method for manufacturing a multilayer printed wiring board with a built-in IC chip. The entire contents of these publications are incorporated herein by reference.

### SUMMARY OF THE INVENTION

According to one aspect of the present invention, a multi-piece substrate includes a frame portion, and a unit portion in which multiple wiring boards is arrayed. The frame portion is formed on the periphery of the unit portion, the wiring boards have semiconductor elements built in the wiring boards, respectively, and the frame portion has multiple slits formed such that the slits have openings on the periphery of the frame portion.

According to another aspect of the present invention, a multi-piece substrate includes a frame portion, and a unit portion in which multiple wiring boards is arrayed. The frame portion is formed on the periphery of the unit portion and has multiple dummy elements positioned such that stresses generated in the frame portion and/or the unit portion are balanced, and the wiring boards have semiconductor elements built in the wiring boards, respectively.

According to yet another aspect of the present invention, a multi-piece substrate includes a frame portion, and a unit portion in which multiple wiring boards is arrayed. The frame portion is formed on the periphery of the unit portion, the wiring boards have semiconductor elements built in the wiring boards, respectively, and the frame portion has multiple slits formed along the boundary between the frame portion and the unit portion and multiple support sections connected to the unit portion.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1(A): a plan view of a multi-piece substrate according to a first embodiment of the present invention, and FIG. 1(B): a plan view of a printed wiring board;

FIG. 2 is a cross-sectional view of a printed wiring board according to the first embodiment;

FIG. 3 is a plan view of a multi-piece substrate according to a first modified example of the first embodiment;

FIG. 4 is a plan view of a multi-piece substrate according to a second modified example of the first embodiment;

FIG. 5 is a plan view of a multi-piece substrate according to a second embodiment;

FIG. 6 is a plan view of a multi-piece substrate according to a reference example;

FIG. 7 is a plan view showing a group of printed wiring boards of a multi-piece substrate according to the reference example; and

FIG. 8 is a plan view showing a group of printed wiring boards of a multi-piece substrate according to a modified example of the reference example.

### DETAILED DESCRIPTION OF THE EMBODIMENTS

The embodiments will now be described with reference to the accompanying drawings, wherein like reference numerals designate corresponding or identical elements throughout the various drawings.

### First Embodiment

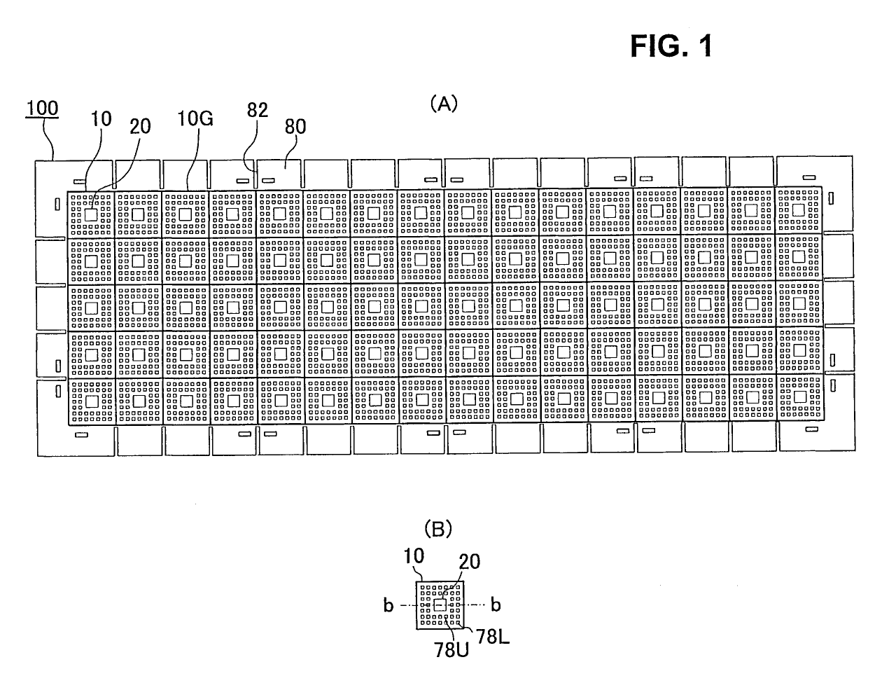

FIG. 1(A) is a plan view of multi-piece substrate 100 according to a first embodiment, and FIG. 1(B) is a plan view of a printed wiring board. Unit section (10G), which contains printed wiring boards 10 arrayed in a matrix of 6 columns×24 rows (5 columns×16 rows in the drawing), is held by frame section 80 of multi-piece substrate 100. IC chip 20 is built into the center of each printed wiring board 10. Solder bumps (78U) for mounting electronic components and solder bumps (78L) for mounting packaging substrates are formed on the upper-surface side. After electronic components and packaging substrates are mounted on the multi-piece substrate, router processing is conducted along the boundary lines of the printed wiring boards so that the printed wiring boards are divided into individual units.

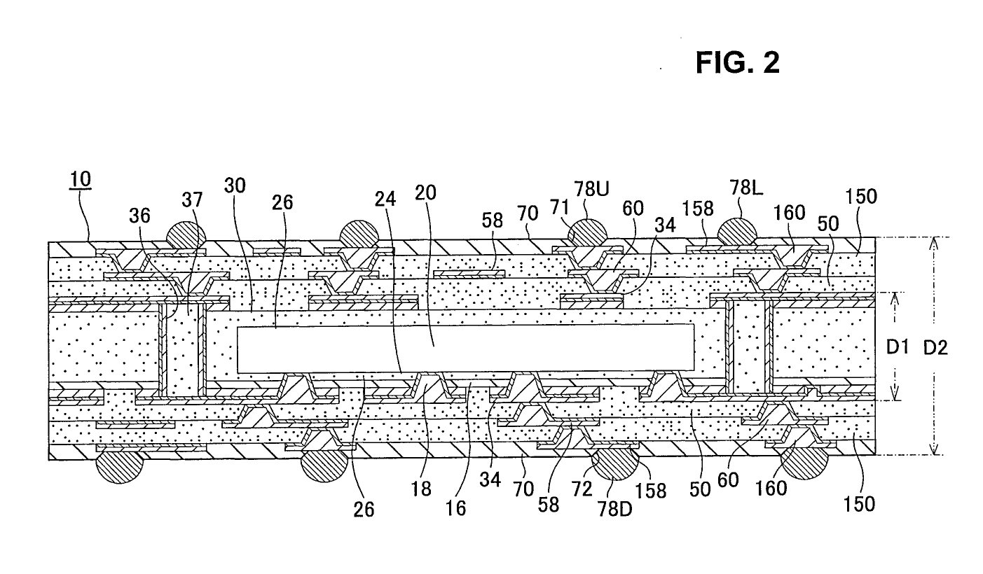

FIG. 2 shows a cross section at the “b-b” in FIG. 1(B). Printed wiring board 10 is made up of core substrate 30 with thickness (D1) of 0.1 mm (including conductive circuits on the upper and lower surfaces) to accommodate IC chip (logic chip) 20, interlayer resin insulation layers 50 and interlayer resin insulation layers 150. The printed wiring board is set to have thickness (D2) of 0.285 mm. The percentage is set at approximately 10% for the areas of the IC chips occupying the entire unit section (10G) in a matrix of 6 columns×24 rows. Via holes 60 and conductive circuits 58 are formed for interlayer resin insulation layers 50, and via holes 160 and conductive circuits 158 are formed for interlayer resin insulation layers 150.

Solder-resist layers 70 are formed on interlayer resin insulation layers 150. Solder bumps (78U) for mounting an electronic component such as a chip capacitor and solder bumps (78L) for mounting a packaging substrate with a memory chip are formed on conductive circuits 158 under opening portions 71 of upper-surface side solder-resist layer 70. Solder bumps (78D) for connection with an external substrate such as a daughterboard or a motherboard not shown in the drawings are formed in opening portions 71 of lower-surface side solder-resist layer 70.

Conductive circuits 34 are formed on both surfaces of core substrate 30. Conductive circuits 34 on both surfaces are connected by through-hole conductors 36 which are filled with resin 37. Conductive circuits 34 on the lower-surface side and terminals 24 of IC chip 20 are connected by via conductors 18 formed in insulation layer 16.

Here, IC chip 20 made of silicon which is ceramic and printed wiring board 10 made of resin have different thermal expansion coefficients. Thus, due to a difference in stresses between IC chip 20 and printed wiring board 10, force is generated to cause warping in frame section 80, which holds printed wiring boards as shown in FIG. 1(A). Therefore, in frame section 80, which holds printed wiring boards arrayed in a matrix in multi-piece substrate 100 of the first embodiment, I-shaped slit 82 is formed along an extended line of the cutting portion of each printed wiring board. Accordingly, stresses caused by a difference in thermal expansion coefficients between built-in IC chips and printed wiring boards are relieved through such slits, warping is prevented, and the flatness of the multi-piece substrate is maintained.

Multiple slits are positioned at equal intervals, and the number of slits is the same in a pair of sides sandwiching the unit section. Accordingly, stresses generated in the multi-piece substrate are set to be symmetrical. Also, by forming slits to have a symmetrical positional relationship in a pair of sides sandwiching the unit section, stresses generated in the multi-piece substrate are set to be symmetrical.

The structure of the first embodiment is especially effective in suppressing warping at a unit section in which printed wiring boards with a thickness of 0.3 mm or less contain core substrates with a thickness of 0.2 mm or less, and in which the percentage of the areas of semiconductor chips occupying such printed wiring boards is 5% or greater.

### First Modified Example of the First Embodiment

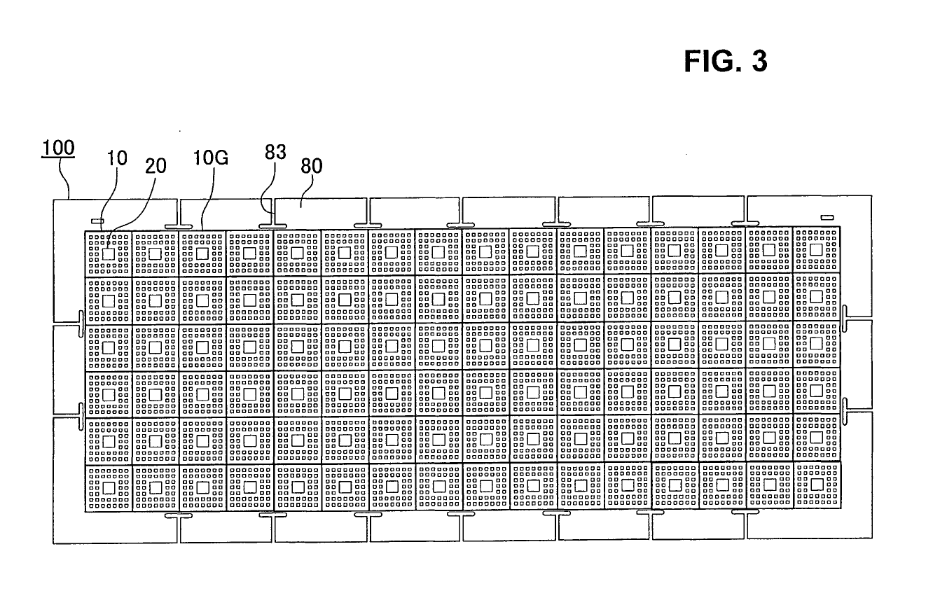

FIG. 3 shows a plan view of multi-piece substrate 100 according to a first modified example of the first embodiment. The same as in the first embodiment, unit section (10G), which contains printed wiring boards 10 arrayed in a matrix of 5 columns×16 rows, is held by frame section 80. IC chip 20 is built into the center of each printed wiring board 10. In a modified example of the first embodiment, T-shaped slit 83 is formed in frame section 80 for every two printed wiring boards.

In multi-piece substrate 100 according to the first modified example of the first embodiment, T-shaped slits 83 are formed, the vertical portion of a T-shape is formed for every two printed wiring boards along an extended line of the cutting portion, and the horizontal portion of the T-shape is formed parallel to the peripheries of the two printed wiring boards. In setting so, stress is relieved from the two printed wiring boards, and the flatness of the multi-piece substrate is maintained. Accordingly, by forming a T-shaped slit for every two or more printed wiring boards, stresses are mitigated and warping is prevented. By setting the intervals of slits wider than the width of the wiring boards, multi-piece substrate 100 is prevented from becoming fragile.

### Modified Example of the First Embodiment

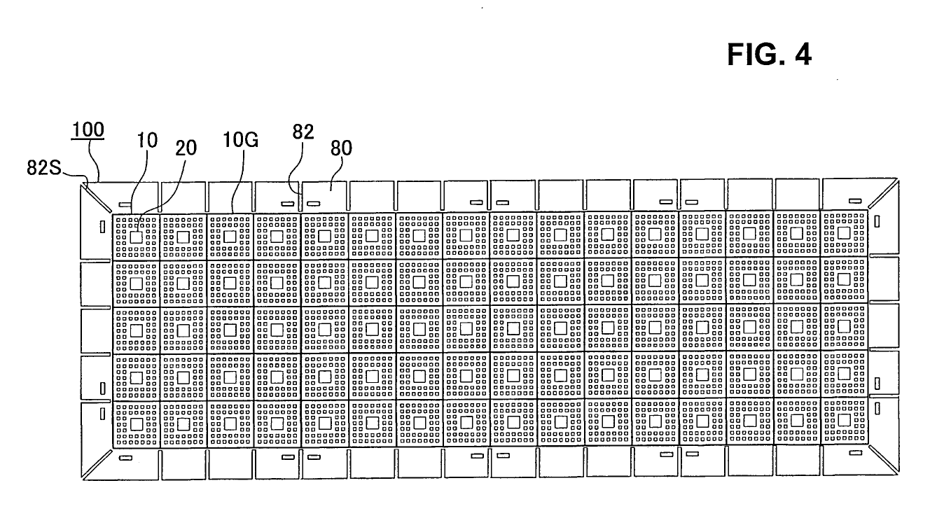

FIG. 4 shows a plan view of multi-piece substrate 100 according to a second modified example of the first embodiment. The same as in the first embodiment, unit section (10G), which contains printed wiring boards 10 arrayed in a matrix of 5 columns×16 rows, is held by frame section 80. IC chip 20 is built into the center of each printed wiring board 10. In the second modified example of the first embodiment, slits (82S) are formed in the four corners of frame section 80.

In multi-piece substrate 100 according to the second modified example of the first embodiment, slits (82S) are formed in the four corners of the frame, where stresses are most likely concentrated. Thus, stresses are mitigated through such slits 82, and warping is prevented.

### Second Embodiment

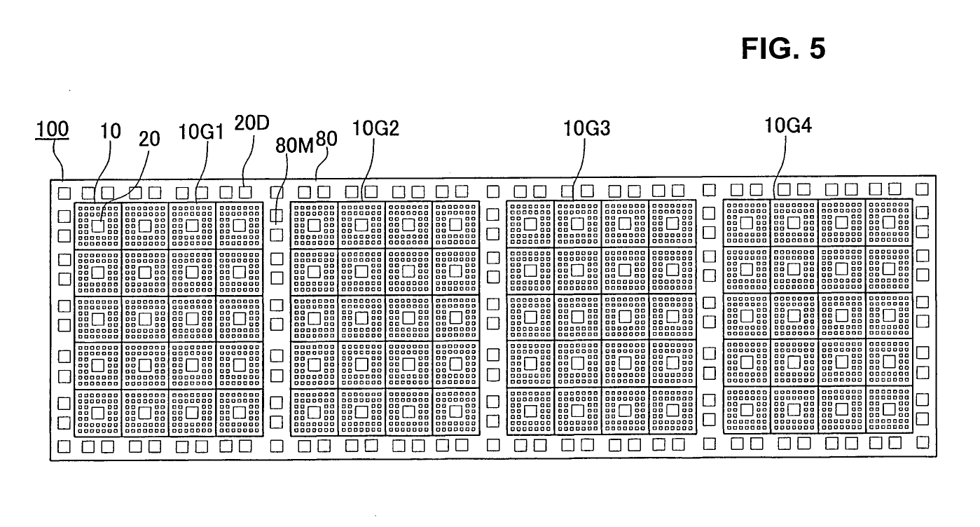

FIG. 5 shows a plan view of multi-piece substrate 100 according to a second embodiment. Four unit sections (10G1, 10G2, 10G3, 10G4) are formed in the second embodiment, each containing printed wiring boards arrayed in a matrix of 5 columns×4 rows. Such unit sections (10G1, 10G2, 10G3, 10G4) are held by middle frame section (80M) between unit section (10G1) and unit section (10G2), middle frame section (80M) between unit section (10G2) and unit section (10G3), middle frame section (80M) between unit section (10G3) and unit section (10G4), and by frame section 80.

Here, dummy chips (20D) having the same shape and the same thickness and made of the same silicon as IC chips 20 are built into frame section 80 and middle frame sections (80M). Two each dummy chips (20D) are accommodated in each side of the printed wiring boards that face frame section 80 or middle frame section (80M).

In a multi-piece substrate of the second embodiment, dummy chips (20D) for balancing stresses are provided in frame section 80, which holds printed wiring boards arrayed in a matrix. Thus, a difference in stresses is not generated between the printed wiring boards and frame section 80, and the flatness of the multi-piece substrate is maintained.

In a multi-piece substrate of the second embodiment, since dummy chips (20D) are shaped the same as IC chips 20, a difference in stresses is not generated between printed wiring boards and frame section 80, and the flatness of the multi-piece substrate is maintained.

In a multi-piece substrate of the second embodiment, two or more dummy chips (20D) per one printed wiring board are provided. Thus, stresses are mitigated through such dummy chips, and the flatness of the multi-piece substrate is maintained.

In a multi-piece substrate of the second embodiment, dummy chips (20D) are provided in middle frame sections (80M) between unit sections. Therefore, even with multiple unit sections containing printed wiring boards arrayed in a matrix, stresses are mitigated among unit sections (10G1, 10G2, 10G3, 10G4) through the dummy chips. Accordingly, the flatness of the multi-piece substrate is maintained.

Since four sets of unit sections (10G1, 10G2, 10G3, 10G4) are formed in a multi-piece substrate of the second embodiment, if a defective portion is found in one printed wiring board, it is required only to dispose of the unit section containing such a defective printed wiring board. Thus, there is no need to dispose of the entire multi-piece substrate with built-in semiconductor elements, and the manufacturing cost of printed wiring boards is reduced.

### Reference Example

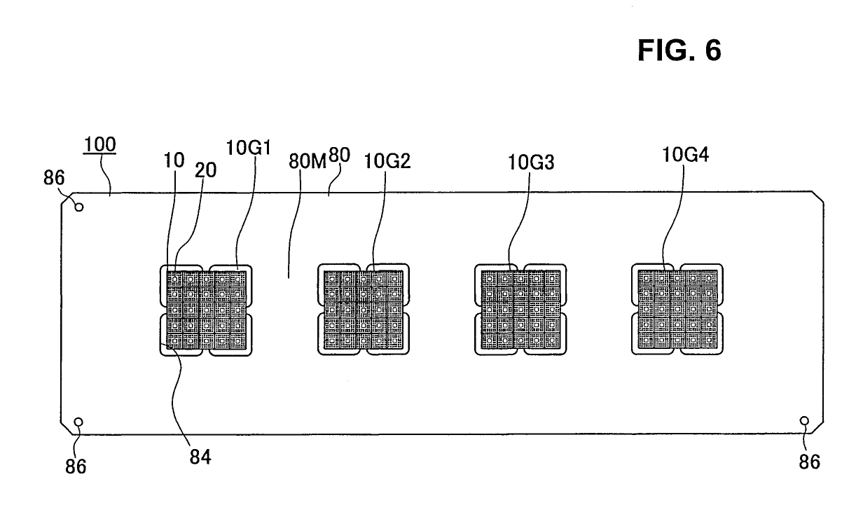

FIG. 6 shows a plan view of multi-piece substrate 100 according to a reference example. Four unit sections (10G1, 10G2, 10G3, 10G4) are formed in the reference example, each containing printed wiring boards 10 that have built-in IC chips 20 and are arrayed in a matrix of 5 columns×5 rows. Such unit sections (10G1, 10G2, 10G3, 10G4) are held by middle frame section (80M) between unit section (10G1) and unit section (10G2), middle frame section (80M) between unit section (10G2) and unit section (10G3), middle frame section (80M) between unit section (10G3) and unit section (10G4), and by frame section 80. Penetrating holes 86 for alignment are formed in three of the corners of frame section 80.

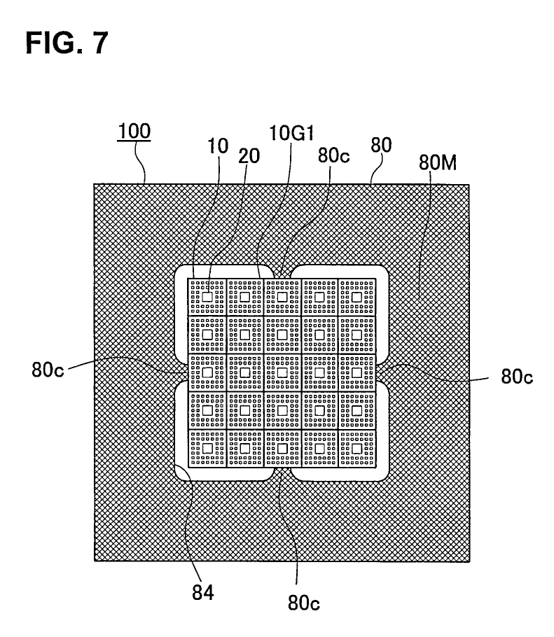

FIG. 7 is an enlarged view of unit section (10G1) shown in FIG. 6. In a multi-piece substrate of the reference example, between unit section (10G1) and frame section 80 or middle frame section (80M) holding the unit section, four L-shaped slits 84 are formed along the outer edges (periphery) of the unit section to separate the corner portions, and the centers of four sides of the unit section are held by frame supports (80c) positioned between such slits. The influence of stresses is disrupted by holding unit section (10G1), which contains printed wiring boards that have built-in IC chips 20 and are arrayed in a matrix, at the centers where the corner portions are positioned symmetrically and stresses are set to be balanced, and by separating the four corners with concentrated stress using slits from frame section 80 and middle frame section (80M). Accordingly, the flatness of the multi-piece substrate is maintained.

### Modified Example of the Reference Example

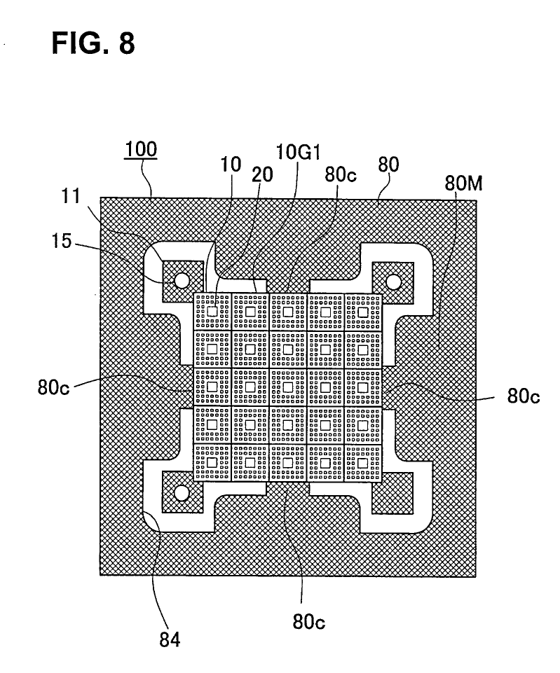

FIG. 8 is an enlarged view of unit section (10G1) according to a modified example of the reference example. The same as in the reference example described above by referring to FIG. 6, four sets of unit sections are positioned on a multi-piece substrate. In a modified example of the reference example, four substantially L-shaped slits 84 are formed between unit section (10G1) and frame section 80 or middle section (80M) holding the unit section, and the centers of four sides of the unit section are held by frame supports (80c). The influence of stresses is disrupted by holding unit section (10G1) at the centers where the corner portions are positioned symmetrically and stresses are set to be balanced, and by separating the four corners with concentrated stress using slits from frame section 80 and middle frame section (80M). Accordingly, the flatness of the multi-piece substrate is maintained.

In a multi-piece substrate according to a modified example of the reference example, alignment-mark positioning members 11 with alignment marks are provided at the four corners of unit section (10G), and penetrating holes 15 for alignment are formed in three of four alignment-mark positioning members 11. In the modified example of the reference example, each unit section is positioned based on alignment marks 15 on each unit section instead of using alignment marks on the multi-piece substrate. Thus, the positional accuracy of each printed wiring board is enhanced.

Since multiple unit sections are formed in multi-piece substrates according to the reference example and modified example of the reference example, when a defective portion is found in one printed wiring board, it is only required to dispose of the unit section containing the defective printed wiring board. Thus, there is no need to dispose of the entire multi-piece substrate with built-in semiconductor elements, and the manufacturing cost of printed wiring boards is reduced.

In the above embodiments, examples are shown in which IC chips are built into printed wiring boards. However, the structures of the present invention are preferably applicable for printed wiring boards with built-in passive elements such as chip capacitors made of ceramic, inductors or resistors in addition to active elements such as IC chips.

When a multi-piece substrate is manufactured for forming multiple printed wiring boards with built-in IC chips, the multi-piece substrate may warp when thermal expansion coefficients are different in IC chips made of silicon and printed wiring boards made of resin. Accordingly, during a process of mounting electronic components such as capacitors on the printed wiring boards of the multi-piece substrate, the influence of such warping makes it difficult to mount electronic components, and their connection reliability is lowered.

According to an embodiment of the present invention, a multi-piece substrate has features as follows: a unit section where multiple wiring boards with built-in semiconductor elements are arrayed; a frame section formed on the periphery of the unit section; and multiple slits formed in the frame section to open toward the outside.

According to another embodiment of the present invention, a multi-piece substrate has features as follows: a unit section where multiple wiring boards with built-in semiconductor elements are arrayed; a frame section formed on the periphery of the unit section; and dummy elements for balancing stresses formed in the frame section.

In a multi-piece substrate according to an embodiment of the present invention, slits are formed in the peripheral frame section, which holds a unit section containing wiring boards arrayed in a matrix. Accordingly, warping caused by stresses generated by a difference in thermal expansion coefficients between the built-in semiconductor elements and the wiring boards is relieved through such slits, and the flatness of the multi-piece substrate is maintained.

In a multi-piece substrate according to another embodiment of the present invention, dummy elements for balancing stresses are provided in the peripheral frame section, which holds a unit section containing wiring boards arrayed in a matrix. Thus, a difference in stresses is not generated between the wiring boards and the frame section, and the flatness of the multi-piece substrate is maintained.

Obviously, numerous modifications and variations of the present invention are possible in light of the above teachings. It is therefore to be understood that within the scope of the appended claims, the invention may be practiced otherwise than as specifically described herein.

What is claimed is:

1. A multi-piece substrate, comprising:
a frame portion; and
a unit portion in which a plurality of wiring boards is arrayed,
wherein the frame portion is formed on periphery of the unit portion, the wiring boards have semiconductor elements built in the wiring boards, respectively, and the frame portion has a plurality of slits formed such that the plurality of slits has openings on periphery of the frame portion.

2. The multi-piece substrate according to claim 1, wherein the plurality of slits is extending to boundary between the unit portion and the frame portion.

3. The multi-piece substrate according to claim 1, wherein the plurality of slits is extending to boundary between the unit portion and the frame portion such that each of the slits is formed substantially in an I shape.

4. The multi-piece substrate according to claim 2, wherein the plurality of slits is extending in a direction parallel to the periphery of the unit portion in vicinity of the boundary between the unit portion and the frame portion.

5. The multi-piece substrate according to claim 2, wherein the plurality of slits is extending in a direction parallel to the periphery of the unit portion in vicinity of the boundary between the unit portion and the frame portion such that each of the slits is formed substantially in a T shape.

6. The multi-piece substrate according to claim 1, wherein the plurality of slits is positioned such that the slits are formed at equal intervals.

7. The multi-piece substrate according to claim 1, wherein the plurality of slits has intervals which are set wider than widths of the printed wiring boards.

8. The multi-piece substrate according to claim 1, wherein the plurality of slits includes slits formed in corners of the frame portion.

9. The multi-piece substrate according to claim 1, wherein the frame portion has a pair of side sections sandwiching the unit portion, and both of the side sections of the frame portion have a same number of slits.

10. The multi-piece substrate according to claim 1, wherein the frame portion has a pair of side sections sandwiching the unit portion, and the plurality of slits is formed in the frame portion such that the slits are positioned in a symmetrical positional relationship in the side sections of the frame portion.

11. The multi-piece substrate according to claim 1, wherein the plurality of slits is formed in the frame portion such that the slits are positioned along extended lines of boundary lines which divide the wiring boards.

12. A multi-piece substrate, comprising:
a frame portion; and
a unit portion in which a plurality of wiring boards is arrayed,
wherein the frame portion is formed on periphery of the unit portion and has a plurality of dummy elements positioned such that stresses generated in at least one of the frame portion and the unit portion are balanced, and the wiring boards have semiconductor elements built in the wiring boards, respectively.

13. The multi-piece substrate according to claim 12, wherein the plurality of dummy elements has a same shape as the semiconductor elements built in the wiring boards.

14. The multi-piece substrate according to claim 13, wherein the plurality of wiring boards includes outer wiring boards positioned along boundary between the frame portion and the unit portion, the plurality of dummy elements is formed such that plural dummy elements are positioned along each of the outer wiring boards.

15. The multi-piece substrate according to claim 12, wherein the unit portion is formed in a plurality such that the plurality of dummy elements includes dummy elements formed between the plurality of unit portions, and each of the unit portions has the wiring boards arrayed in a matrix.

16. The multi-piece substrate according to claim 12, wherein the plurality of dummy elements is built in the frame portion.

17. A multi-piece substrate, comprising:
a frame portion; and
a unit portion in which a plurality of wiring boards is arrayed,
wherein the frame portion is formed on periphery of the unit portion, the wiring boards have semiconductor elements built in the wiring boards, respectively, and the frame portion has a plurality of slits formed along a boundary between the frame portion and the unit portion and a plurality of support sections connected to the unit portion.

18. The multi-piece substrate according to claim 17, wherein the plurality of slits is formed such that the plurality of slits is positioned to surround corner portions of the unit portion.

19. The multi-piece substrate according to claim 17, further comprising a plurality of positioning members comprising a plurality of alignment marks, respectively, wherein the plurality of positioning members is positioned at corner portions of the unit portion, respectively.

20. The multi-piece substrate according to claim 17, further comprising a plurality of positioning members comprising a plurality of alignment marks, respectively, wherein the plurality of positioning members is positioned at corner portions of the unit portion, respectively, and the plurality of slits is formed such that the plurality of slits is positioned to surround the corner portions of the unit portion.
